(19) United States
(12) Patent Application Publication
(10) Pub. No.: US 2024/0332444 A1
(43) Pub. Date: Oct. 3, 2024

(54) OPTOELECTRONIC DEVICE

(71) Applicant: AMS-OSRAM International GmbH, Regensburg (DE)

(72) Inventors: Alvaro GOMEZ-IGLESIAS, Regensburg (DE); Norwin VON MALM, Nittendorf (DE); Tansen VARGHESE, Regensburg (DE); Dirk BECKER, Langquaid (DE)

(73) Assignee: ams-OSRAM International GmbH, Regensburg (DE)

(21) Appl. No.: 18/699,385

(22) PCT Filed: Aug. 11, 2022
(86) PCT No.: PCT/EP2022/072564

§ 371 Date: Apr. 8, 2024

(30) Foreign Application Priority Data
Oct. 15, 2021 (DE) 102021126739.0

(51) Int. Cl. H01L 31/167; H01L 31/0216; H01L 31/0232; H01L 31/0304; H01L 31/0352; H01L 31/0687; H02J 50/30

(52) U.S. Cl. CPC H01L 31/167; H01L 31/02161; H01L 31/02327; H01L 31/03046; H01L 31/035236; H01L 31/0687; H02J 50/30

(57) ABSTRACT

An optoelectronic device is specified, including an emitter, operated with an electrical input voltage and configured to emit electromagnetic radiation during operation, a receiver, configured to convert electromagnetic radiation emitted by the emitter to an output voltage, wherein the receiver includes a semiconductor layer sequence with a plurality of stacked active layers, electromagnetic radiation emitted by the emitter is coupled into the receiver via a first side face of the semiconductor layer sequence, and the electromagnetic radiation propagates parallel to a main extension plane of the active layer inside the active layer, where it is gradually absorbed and converted into an electrical voltage.

### CROSS-REFERENCE TO RELATED APPLICATIONS

The present application is a national stage entry from International Application No. PCT/EP2022/072564, filed on Aug. 11, 2022, published as International Publication No. WO 2023/061637 A1 on Apr. 20, 2023, and claims priority to German Patent Application No. 10 2021 126 739.0, filed Oct. 15, 2021, the disclosures of all of which are hereby incorporated by reference in their entireties.

### FIELD

An optoelectronic device is specified herein.

### BACKGROUND

At least one object of certain embodiments is to specify an optoelectronic device, which can be designed to be particularly compact. This object is achieved by the subject matter according to the independent claim. Advantageous embodiments and developments of the optoelectronic device are given in the dependent claims and are also disclosed by the following description and the drawings.

### SUMMARY

According to an embodiment the optoelectronic device comprises an emitter, wherein the emitter is operated with an electrical input voltage and configured to emit electromagnetic radiation during operation.

For example, the emitter is configured to generate electromagnetic radiation in the wavelength range between infrared radiation and ultraviolet radiation. In particular, the emitter may be configured to generate electromagnetic radiation in the wavelength range between at least 350 nanometer to at most 1100 nanometer. Preferably, the emitter comprises a planar, main radiation outcoupling surface through which a major part of the generated electromagnetic radiation is emitted. For example, at least 90% of the generated electromagnetic radiation is emitted through the main radiation outcoupling surface of the emitter.

According to an embodiment the optoelectronic device comprises a receiver, wherein the receiver is configured to convert electromagnetic radiation emitted by the emitter to an output voltage.

Preferably, the output voltage of the receiver is larger than the input voltage of the emitter. For example, the input voltage may be between 1 Volt and 10 Volts, inclusive, whereas the output voltage may be between 10 Volts and 10000 Volts, inclusive. Alternatively, the output voltage of the receiver may be equal to or smaller than the input voltage of the emitter. The input voltage of the emitter and the output voltage of the receiver may be a DC voltage or an AC voltage. A maximum frequency of the AC voltage is determined by a switching time of the emitter and by a response time of the receiver. For example, the maximum frequency may be 10 Megahertz.

Preferably, the optoelectronic device is improved, such that the receiver has a particularly large absorption rate for electromagnetic radiation emitted by the emitter. In particular, electromagnetic radiation, which is absorbed by the receiver, is converted to the electrical output voltage via a photovoltaic effect, for example.

For example, the emitter is a light emitting diode, a vertical-cavity surface-emitting laser diode (VCSEL), or preferably an edge-emitting laser diode.

Preferably, the emitter comprises or consists of a semiconductor material from one of the following material systems: a nitride compound semiconductor, a phosphide compound semiconductor, or an arsenide compound semiconductor. A nitride compound semiconductor preferably comprises AlₙGaₘIn₁₋ₙ₋ₘN, with 0≤n≤1, 0≤m≤1 and n+m≤1. A phosphide compound semiconductor preferably comprises AlₙGaₘIn₁₋ₙ₋ₘP, with 0≤ n≤1, 0≤ m≤1 and n+m≤1. An arsenide compound semiconductor preferably comprises AlₙGaₘIn₁₋ₙ₋ₘAs, with 0 $ n $1, 0≤ m≤1 and n+m≤1. In addition, these compound semiconductors may also comprise one or more dopant materials, as well as other components.

The optoelectronic device may also comprise a plurality of emitters, wherein the electromagnetic radiation emitted by the plurality of emitters is superimposed on a radiation incoupling surface of the receiver, for example.

According to an embodiment of the optoelectronic device the receiver comprises a semiconductor layer sequence with a plurality of stacked active layers.

The features described in the following for a single active layer preferably apply to all active layers in the semiconductor layer sequence of the receiver.

The active layer is configured to absorb electromagnetic radiation emitted by the emitter, and to convert it into an electrical output voltage. The active layer preferably comprises a p-doped semiconductor layer and an n-doped semiconductor layer forming a pn-junction.

The pn-junction may comprise a multi quantum well structure. A multi quantum well structure comprises a plurality of quantum well layers separated by barrier layers. The barrier layers preferably exhibit a larger band gap than the quantum well layers. The arrangement of quantum well layers and barrier layers leads to a confinement of electric charges in the quantum well layers, giving rise to discrete energy values for the confined electric charges.

Preferably, the semiconductor layer sequence of the receiver comprises a semiconductor material from the same material system as the semiconductor material of the laser diode. For example, the semiconductor layer sequence of the receiver comprises a nitride compound semiconductor, a phosphide compound semiconductor, or an arsenide compound semiconductor. The semiconductor layer sequence may comprise between 1 and 1000 active layers, inclusive.

The active layer may have a thickness between 10 nanometer and 1 micrometer, inclusive. Preferably, the thickness of the active layer is between 20 nanometer and 100 nanometer. Here and in the following, the thickness refers to an average extension of the layer in growth direction of the semiconductor layer sequence.

Preferably, the stacked active layers in the semiconductor layer sequence of the receiver are electrically connected in series, such that the electrical output voltage of each active layer adds up to the output voltage of the receiver. The pn-junctions of the stacked active layers preferably have the same orientation in a growth direction of the semiconductor layer sequence, such that the stack of active layers is electrically connected in series. A tunnel junction is preferably arranged between each pair of active layers.

Accordingly, the receiver may form a multi-junction photovoltaic cell.

According to an embodiment of the optoelectronic device electromagnetic radiation emitted by the emitter is coupled into the receiver via a first side face of the semiconductor layer sequence.

In particular, electromagnetic radiation emitted by the emitter is not coupled into the receiver via a surface that is parallel to a main extension plane of the active layer. For example, the first side face is perpendicular to the main extension plane of the active layer. Alternatively, the surface normal to the first side face may also enclose an angle between 0° degrees and 90° degrees with a surface normal to the main extension plane of the active layer.

According to an embodiment of the optoelectronic device the electromagnetic radiation, which is emitted by the emitter and coupled into the receiver via the first side face, propagates parallel to the main extension plane inside the active layer, where it is gradually absorbed and converted into an electrical voltage.

According to a preferred embodiment, the optoelectronic device comprises:
an emitter, operated with an electrical input voltage and configured to emit electromagnetic radiation during operation,
a receiver, configured to convert electromagnetic radiation emitted by the emitter to an output voltage, wherein
the receiver comprises a semiconductor layer sequence with a plurality of stacked active layers,
electromagnetic radiation emitted by the emitter is coupled into the receiver via a first side face of the semiconductor layer sequence, and
the electromagnetic radiation propagates parallel to a main extension plane of the active layer inside the active layer, where it is gradually absorbed and converted into an electrical voltage.

Many applications, such as acoustics, beam steering technologies like micro-electro-mechanical systems (MEMS), actuators, detectors, in particular avalanche photo diodes, single-photon avalanche diodes and photomultipliers, require high voltage supplies with relatively low power consumption. In particular, such applications might require voltages larger than 50 Volt, 100 Volt, 500 Volt, 1000 Volt, 2000 Volt, or 10000 Volt, while, at the same time, preserving a small footprint of the device in terms of size, weight, cost and energy consumption. These features are of particular importance for mobile devices, such as augmented-reality or virtual-reality glasses, wearable in-ear speakers and also for automotive applications, for example.

Another problem for small-footprint, high-voltage generators is the connection of low-voltage paths and high-voltage paths, which should be galvanically separated to ensure functional safety and long-term stability of a device under varying environmental conditions, such as temperature, humidity, dust. Here and in the following, galvanical separation means that there is no direct contact and/or no direct electrical connection between low-voltage paths and high-voltage paths.

The optoelectronic device described herein is configured as an optical voltage converter, which may be designed to be particularly compact. In particular, it does not require bulky coils or capacitors. Moreover, the optoelectronic device described herein takes advantage of a high power and a high wall-plug efficiency of edge emitting laser diodes. A single emitter or only a small number of emitters may thus be sufficient to illuminate the receiver, such that the size and cost on the emitter side are reduced. Furthermore, the receiver preferably comprises a stack of active layers separated by tunnel junctions. This mitigates the risk of a high voltage breakdown or of electromigration between metallization traces that might affect compact arrays of single-junction photovoltaic cells connected in series.

Preferably, the emitter and the receiver are arranged on a common carrier, such that electromagnetic radiation emitted by the emitter directly illuminates the first side face of the receiver. In particular, electromagnetic radiation emitted by the emitter does not need to be redirected onto the first side face of the receiver. This simplifies a packaging of the optoelectronic device. Moreover, no additional optics may be required between the emitter and the receiver. A galvanic separation between the emitter and the receiver can be ensured by a wireless power transmission between the emitter and the receiver via laser light.

According to an embodiment of the optoelectronic device the emitter comprises an edge-emitting laser diode.

The edge-emitting laser diode is configured to emit laser radiation with a wavelength between at least 350 nanometer and at most 1100 nanometer. Laser radiation is generated via stimulated emission and exhibits a large coherence length, a small spectral bandwidth and/or a high degree of polarization compared to electromagnetic radiation generated by spontaneous emission.

According to an embodiment the optoelectronic device further comprises cladding layers, wherein two cladding layers are arranged on main faces of the active layer, such that two cladding layers and the active layer form a waveguide for the electromagnetic radiation propagating inside the active layer. In other words, the semiconductor layer sequence of the receiver comprises alternatingly arranged active layers and cladding layers, wherein outer main surfaces of the semiconductor layer sequence are formed by a cladding layer.

Preferably, the semiconductor layer sequence of the receiver comprises a periodic layer stack. In particular, one period of the semiconductor layer stack may comprise one tunnel junction, two cladding layers and one active layer arranged between the two cladding layers.

Here and in the following main faces of the active layer are parallel to a main extension plane of the active layer. In other words, main faces of the active layer are perpendicular to the growth direction of the semiconductor layer sequence.

Preferably, the cladding layers are a part of the semiconductor layer sequence of the receiver and comprise a semiconductor material with a larger band gap than the active layer. In particular, a refractive index of the cladding layer is smaller than a refractive index of the active layer. Electromagnetic radiation propagating in the active layer is preferably totally reflected at a boundary between the active layer and the cladding layer. The active layer and the two cladding layers preferably form a multimode waveguide. In particular, electromagnetic radiation emitted by the emitter and coupled into the receiver via the first side face propagates within each active layer in the form of multiple modes.

According to an embodiment of the optoelectronic device a length of the receiver in propagation direction of the electromagnetic radiation is smaller than an absorption length of the electromagnetic radiation in the active layer.

The absorption length is a characteristic property of the semiconductor material of the active layer. In particular, an intensity of electromagnetic radiation decreases by about 63% after propagating a distance equal to the absorption length inside the semiconductor material.

A density of free electric charge carriers generated due to the absorption of electromagnetic radiation in the active layer is proportional to the intensity of the electromagnetic radiation. In other words, the electrical voltage generated by a region of the active layer is proportional to the intensity of the electromagnetic radiation in this region of the active layer. For example, a region of the active layer exposed to electromagnetic radiation with a smaller intensity compared to a second region generates a smaller output voltage than the second region.

Within a simplified equivalent circuit diagram, different regions of the active layer can be viewed as separate photodiodes, which are electrically connected in parallel. Consequently, the region of the active layer where the intensity of electromagnetic radiation is smallest, generates the smallest electrical output voltage and pulls the overall output voltage of the equivalent circuit down. In other words, the region of the active layer where the intensity of electromagnetic radiation is smallest determines the overall output voltage of the active layer. Since electromagnetic radiation emitted by the emitter is absorbed while propagating inside the active layer, the region of the active layer furthest downstream in propagation direction of the electromagnetic radiation determines the output voltage of the active layer.

In order to generate a large output voltage of the receiver and/or to increase an efficiency of the optoelectronic device, the intensity of electromagnetic radiation within the active layer is preferably as homogenous as possible. Accordingly, it can be advantageous, if the length of the receiver in propagation direction of the electromagnetic radiation is smaller than the absorption length of the semiconductor material of the active region.

According to an embodiment a length of the receiver in propagation direction of the electromagnetic radiation is larger than a wavelength of the electromagnetic radiation.

According to an embodiment of the optoelectronic device a thickness of the active layer increases from a center of the receiver in a direction parallel to a growth direction of the semiconductor layer sequence.

Electromagnetic radiation emitted by the emitter is preferably coupled into the receiver via the first side face. An illumination of the first side face by the electromagnetic radiation emitted by the emitter may not be uniform, however. For example, the intensity of electromagnetic radiation propagating in active layers closer to the outer main surface of the semiconductor layer sequence may be smaller than the intensity of electromagnetic radiation in an active layer at the center of the semiconductor layer sequence. In order to compensate an inhomogeneous intensity profile of electromagnetic radiation across a growth direction of the semiconductor layer sequence, the thickness of the active layers may increase from the center of the receiver in both directions parallel to the growth direction.

According to an embodiment the optoelectronic device further comprises an optical element, which is arranged between the emitter and the receiver. For example, the optical element comprises an optical lens, a microlens array, a phase array, and/or a diffractive optical element. The optical element is configured to homogenize an intensity profile of the electromagnetic radiation emitted by the emitter across the first side face of the semiconductor layer sequence of the receiver. A homogenous intensity profile of the electromagnetic radiation across the first side face may be advantageous. For example, each active layer in the semiconductor layer sequence is exposed to the same intensity of electromagnetic radiation and thus generates the same output voltage.

According to an embodiment of the optoelectronic device the first side face of the semiconductor layer sequence of the receiver comprises an antireflective coating. Particularly, the antireflective coating reduces a reflection of electromagnetic radiation of the emitter. For example, the antireflective coating reflects electromagnetic radiation of the emitter by at most 10%, preferably by at most 5%. The antireflective coating is configured to increase an incoupling efficiency of electromagnetic radiation emitted by the emitter and coupled into the receiver via the first side face.

According to an embodiment of the optoelectronic device a second side face of the semiconductor layer sequence of the receiver opposite to the first side face comprises a highly reflective coating.

The highly reflective coating is configured to reflect a majority of electromagnetic radiation emitted by the emitter after passing through the receiver once. For example, the highly reflective coating has a reflectivity of more than 90%, preferably more than 99%, for electromagnetic radiation emitted by the emitter and propagating inside the active layer. In particular, the highly reflective coating is configured to homogenize an intensity profile of electromagnetic radiation in propagation direction across the main extension plane of the active layer.

According to an embodiment of the optoelectronic device the first side face and the second side face of the semiconductor layer sequence of the receiver comprise a highly reflective coating, such that the first side face and the second side face form an optical resonator for electromagnetic radiation emitted by the emitter.

The optical resonator is configured such that electromagnetic radiation emitted by the emitter and coupled into the receiver propagates inside the active layers of the receiver multiple times between the two highly reflective coatings, before it is fully absorbed by the active layers. For example, the electromagnetic radiation propagates at least twice the length of the receiver before being fully absorbed. The optical resonator thus gives rise to a more homogeneous intensity profile of the electromagnetic radiation in propagation direction across the main extension plane of the active layer.

According to an embodiment of the optoelectronic device tunnel junctions are arranged between the active layers. Since the stack of active layers may comprise pn-junctions, wherein each pn-junction has the same orientation, arranging tunnel junctions between the pn-junctions is advantageous.

According to an embodiment of the optoelectronic device a thickness of the tunnel junction is at most 100 nanometers. In order to avoid losses in tunnel junctions, thin tunnel junctions are advantageous. Moreover, the doping of the tunnel junctions can be reduced as much as possible, in order to minimize free carrier absorption in the tunnel junctions. Furthermore, a material of the tunnel junction can be chosen to avoid interband absorption. For an optoelectronic device configured for voltage conversion, where the operating electric current may be small, tunnel junctions with a thickness of at most 100 nanometers can be sufficient.

According to an embodiment of the optoelectronic device at least one active layer comprises a multi quantum well structure comprising indium gallium arsenide, and at least one tunnel junction comprises gallium arsenide. In particular, indium gallium arsenide preferably comprises In₁₋ₘGaₘAs, with 0≤ m≤1, whereas gallium arsenide corresponds to m=1. Furthermore, these semiconductor materials may comprise one or more dopant materials.

According to an embodiment of the optoelectronic device at least one active layer with a bulk pn-junction comprises gallium arsenide, and at least one tunnel junction comprises aluminum gallium arsenide.

A bulk pn-junction does not comprise additional structures for a confinement of electric charges, such as single quantum wells or multi quantum wells. In particular, a bulk pn-junction allows for almost continuous energy values of electric charges.

Aluminium gallium arsenide preferably comprises Al₁₋ₙGaₙAs, with 0≤ n≤1. Furthermore, these semiconductor materials may comprise one or more dopant materials.

According to an embodiment of the optoelectronic device a width of the receiver in a direction perpendicular to the growth direction of the semiconductor layer sequence and perpendicular to the propagation direction of the electromagnetic radiation in the active layers decreases in the propagation direction.

Since electromagnetic radiation emitted by the emitter is gradually absorbed during propagation in the active layers, the intensity of electromagnetic radiation decreases in the active layer in propagation direction. In order to achieve a more homogeneous intensity profile of electromagnetic radiation propagating inside the active layer, a decreasing width of the receiver in propagation direction may be advantageous. In particular, outer faces of the receiver may function as waveguides for electromagnetic radiation propagating in the active layers. For example, in the absence of absorption inside the active layers, a decreasing width of the receiver in propagation direction would therefore lead to an enhancement of the intensity and/or irradiance of electromagnetic radiation in propagation direction. The combination of absorption in the active layer and a decreasing width of the receiver in propagation direction can lead to a more homogenous intensity profile of the electromagnetic radiation in propagation direction inside the active layer. In other words, the decreasing width of the receiver can compensate the absorption inside the active layer in order to a achieve a more homogeneous intensity profile. For example, the width of the receiver may decrease linearly or exponentially in propagation direction of electromagnetic radiation.

According to an embodiment the optoelectronic device further comprises a second emitter configured to emit electromagnetic radiation during operation, wherein electromagnetic radiation emitted by the second emitter is coupled into the receiver via a second side face of the semiconductor layer sequence opposite to the first side face.

In this case, the first side face and the second side face preferably comprise antireflective coatings. The antireflective coatings are configured to reduce the reflection of electromagnetic radiation of the emitters at the first side face and at the second side face. For example, at most 5% of electromagnetic radiation of the emitters is reflected by the antireflective coating. The superposition of counter propagating electromagnetic radiation emitted by the two emitters inside the receiver can give rise to a more homogenous intensity profile of electromagnetic radiation inside the active layer of the receiver.

According to an embodiment of the optoelectronic device wavelengths of electromagnetic radiation emitted by the two emitters differs by not more than 10 nanometers.

If the length of the receiver in propagation direction of the electromagnetic radiation is shorter than the absorption length of electromagnetic radiation in the active layer, a fraction of the electromagnetic radiation emitted by one emitter may pass through the receiver and couple into the second emitter. This can lead to problems during operation of the emitters. For example, in order to avoid an interference of electromagnetic radiation generated by the two emitters inside one of the respective emitters, it may be advantageous if the two emitters facing each other emit electromagnetic radiation with wavelengths differing by not more than 10 nanometers. Further, electromagnetic radiation emitted by one of the emitters can be coupled into the receiver at a small angle with respect to a surface normal to the first or to the second side face of the semiconductor layer sequence. For example, the angle may be at most 10 degrees.

According to an embodiment the optoelectronic device further comprises a plurality of receivers arranged next to each other on a common substrate and electrically connected to each other in series, wherein the plurality of receivers is arranged between the two emitters.

In particular, the receivers are preferably arranged such that the second side face of a first receiver faces the first side face of a directly neighboring second receiver and analogously for further receivers. In such an arrangement electromagnetic radiation emitted by the first emitter and not absorbed in the first receiver, further couples into the second receiver via the first side face of the second receiver, for example. Accordingly, a plurality of receivers can be arranged next to each other such that the electromagnetic radiation emitted by the emitter is fully absorbed by the plurality of receivers, while maintaining an almost homogenous intensity profile of electromagnetic radiation within each receiver. In particular, the length of the receiver in propagation direction may be smaller than the absorption length, while the total length of the plurality of receivers may be larger than the absorption length, for example by a factor of 10. Alternatively, the plurality of receivers may also be driven by a single emitter.

According to an embodiment of the optoelectronic device the receiver comprises a dielectric coating on side faces of the semiconductor layer sequence. The dielectric coating preferably comprises a dielectric material with a lower refractive index than the semiconductor layer sequence.

Preferably, the dielectric coating is arranged on side faces of the semiconductor layer sequence that are not configured for incoupling and/or outcoupling of electromagnetic radiation emitted by the emitter. In particular, the dielectric coating is configured as a passivation in order to avoid electrical short circuits of the stack of active layers.

Further advantageous embodiments and further embodiments of the optoelectronic device will become apparent from the following exemplary embodiments described in connection with the Figures.

### BRIEF DESCRIPTION OF THE DRAWINGS

FIG. 1 shows a schematic cross-section of the optoelectronic device according to an exemplary embodiment.

FIG. 2 shows a schematic cross-section of a part of the stack of active layers in the receiver together with a schematic intensity profile of electromagnetic radiation according to an exemplary embodiment.

FIG. 3 shows a schematic cross-section of a receiver according to an exemplary embodiment.

FIGS. 4 and 5 show schematic illustrations of the band gap within one period of the active layer stack according to exemplary embodiments.

FIG. 6 shows a schematic diagram of the intensity profile of electromagnetic radiation inside a receiver as a function of the propagation direction according to an exemplary embodiment.

FIG. 7 shows a schematic cross-section of a receiver according to a further exemplary embodiment.

FIGS. 8 and 9 show schematic plan views of a receiver together with schematic intensity profiles across the width of the receiver according to exemplary embodiments.

FIG. 10 shows a schematic side cross-section of a receiver according to a further exemplary embodiment.

FIG. 11 shows a schematic cross-section of an optoelectronic device according to a further exemplary embodiment.

FIG. 12 shows a schematic plan view of an optoelectronic device according to an exemplary embodiment.

### DETAILED DESCRIPTION

Elements that are identical, similar, or have the same effect, are denoted by the same reference signs in the Figures. The Figures and the proportions of the elements shown in the Figures are not to be regarded as true to scale. Rather, individual elements, in particular layer thicknesses, may be shown exaggeratedly large for better representability and/or better understanding.

The optoelectronic device according to the exemplary embodiment of FIG. 1 comprises an emitter 1 and a receiver 3. The emitter 1 is an edge-emitting laser diode 4 operated with an electrical input voltage Vin. The receiver 3 comprises a semiconductor layer sequence 5 with electrical contacts 19 on opposite main faces of the semiconductor layer sequence 5. Main faces are perpendicular to a growth direction 11 of the semiconductor layer sequence 5. The semiconductor layer sequence 5 comprises a plurality of stacked active layers 6. The active layers 6 comprise pn-junctions and are configured to absorb electromagnetic radiation 2 emitted by the emitter 1. The active layers 6 have a thickness 10 between 100 nanometer and 10 micrometer inclusive.

Electromagnetic radiation 2 emitted by the emitter 1 is coupled into the receiver 3 via a first side face 7 of the semiconductor layer sequence 5. Here, the side face 7 is orthogonal to a main face of the semiconductor layer sequence 5. The electromagnetic radiation 2 thus propagates inside the receiver 3 in a propagation direction 18 along a main extension plane of the active layers 6 while being gradually absorbed.

The receiver 3 is configured to generate an electrical output voltage Vₒᵤₜ. The electrical output voltage Vₒᵤₜ is preferably larger than the electrical input voltage Vin of the emitter 1. The emitter 1 and the receiver 3 are not in direct contact and thus galvanically isolated from each other. A length 9 of the receiver in propagation direction 18 of the electromagnetic radiation 2 is smaller than an absorption length L_{abs} of electromagnetic radiation inside the active layer 6.

Each active layer 6 is arranged between two cladding layers 8 (the cladding layers 8 are not shown in FIG. 1). The cladding layers 8 have a lower refractive index than the active layer 6. The combination of the active layer 6 and the two cladding layers 8 is configured as a waveguide for electromagnetic radiation 2 propagating inside the active layer 6. In particular, electromagnetic radiation 2 emitted by the emitter 1 and coupled into the receiver 3 via the first side face 7 propagates inside the active layer 6 in the form of multiple waveguide modes. In particular, the electromagnetic radiation 2 and is totally reflected at a boundary between the active layer 6 and the cladding layer 8. The active layer 6 and the two cladding layers 8 are configured as a multimode waveguide.

The pn-junctions of the active layers 6 are oriented in the same direction, such that the pn-junctions of the stack of active layers 6 are electrically connected in series. Tunnel junctions 15 are arranged between the active layers 6. The semiconductor layer sequence 5 thus forms a multi-junction photovoltaic cell.

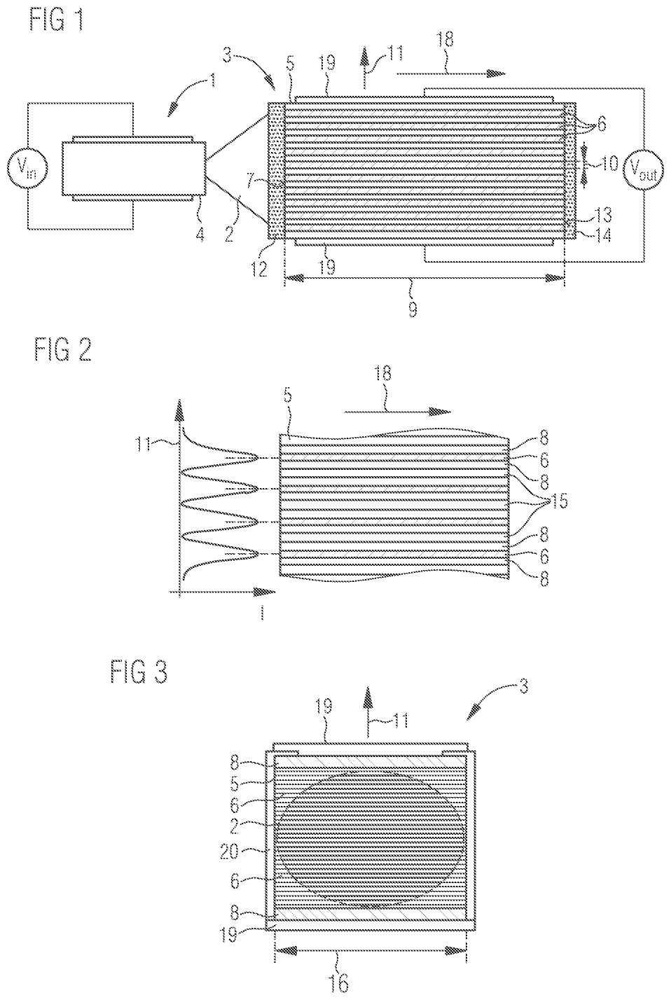

FIG. 2 shows a schematic intensity profile of electromagnetic radiation 2 according to an exemplary embodiment. The graph shows an intensity I of electromagnetic radiation 2 as function of a growth direction 11 across a part of a semiconductor layer sequence 5 of a receiver 3. In particular, four active layers 6 with surrounding cladding layers 8, separated by tunnel junctions 15 are shown.

Electromagnetic radiation 2 emitted by an emitter 1 and coupled into the receiver 3 via a first side face 7 of the semiconductor layer sequence 5, propagates within the active layers 6. Its propagation direction 18 is parallel to a main extension plane of the active layers 6. The intensity profile shows modes of electromagnetic radiation 2 propagating within the active layers 6. In particular, the intensity I of electromagnetic radiation 2 is peaked inside the active layers 6.

A schematic cross-section of a receiver 3 viewed from a emitter 1 is shown in the exemplary embodiment of FIG. 3. Side faces of the receiver 3 which are not configured for coupling electromagnetic radiation 2 into the receiver 3 are covered with a dielectric coating 20. The dielectric coating 20 comprises a lower refractive index for electromagnetic radiation 2 propagating inside the receiver 3 than the semiconductor layer sequence 5. The dielectric coating 20 is configured as a waveguide for electromagnetic radiation 2 propagating inside the active layers 6. Furthermore, the dielectric coating 20 is configured as a passivation, in order to protect the semiconductor layer sequence 5 from electrical short circuits. Additional cladding layers 8 are arranged on outer main surfaces of the semiconductor layer sequence 5. The cladding layers 8 on the outer main surfaces are preferably thicker than cladding layers 8 within the semiconductor layer sequence 5. The cladding layers 8 on the outer main surfaces are configured to keep waveguide modes of electromagnetic radiation 2 propagating within the active layers 6 away from electrical contacts 19. The latter are disposed on the outer main surfaces of the semiconductor layer sequence 5.

The electrical contacts 19 on the outer main surfaces of the semiconductor layer sequence 5 preferably comprise a metal. Moreover, the electrical contacts 19 cover the entire outer main surfaces of the semiconductor layer sequence 5. The dashed ellipse in FIG. 3 indicates a region of the first side face 7 of the semiconductor layer sequence 5 of the receiver 3. This region is illuminated by electromagnetic radiation 2 emitted by the emitter 1.

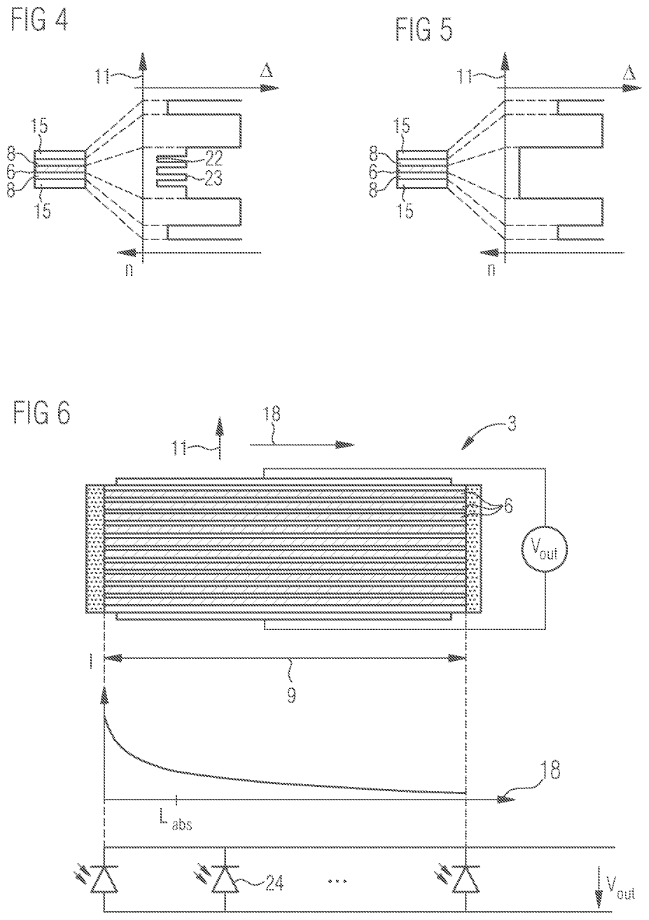

A schematic diagram of a band gap Δ across a period of the semiconductor layer sequence 5 of the receiver 3 is shown in the exemplary embodiment of FIG. 4. The period comprises a tunnel junction 15, as well as an active layer 6 embedded within two cladding layers 8. The band gap Δ of a semiconductor material of the semiconductor layer sequence 5 is approximately inversely proportional to a refractive index n of the semiconductor material.

The active layer 6 comprises a multi quantum well structure, with a plurality of quantum well layers 22 separated by barrier layers 23. The barrier layers 23 have a larger band gap Δ than the quantum well layers 22. The quantum well layers 22 are configured to absorb electromagnetic radiation 2 emitted by the emitter 1. The cladding layers 8 on each side of the active layer 6 comprise a semiconductor material with a larger band gap Δ than the active layer 6.

Accordingly, the cladding layers 8 have a smaller refractive index n than the active layer 6. Electromagnetic radiation 2 propagating within the active layer 6 thus may be internally reflected at a boundary between the active layer 6 and the cladding layer 8.

In this exemplary embodiment the quantum well layers 22 comprise indium gallium arsenide and the tunnel junctions 15 comprise gallium arsenide. The quantum well layers 22 are configured to absorb electromagnetic radiation 2 with a wavelength that is larger than or equal to 900 nanometer. FIG. 5 shows a schematic diagram of the band gap Δ of one period of the semiconductor layer sequence 5 according to a further exemplary embodiment. In contrast to FIG. 4, the active layer 6 is configured as a bulk pn-junction and is embedded between two cladding layers 8. In particular, the active layer 6 does not comprise a quantum well structure. In this exemplary embodiment the active layer 6 comprises gallium arsenide and the tunnel junctions 15 comprise aluminium gallium arsenide. In particular, the active layer 6 is configured to absorb electromagnetic radiation 2 with a wavelength of approximately 850 nanometer.

FIG. 6 shows an exemplary schematic diagram of the intensity I of electromagnetic radiation 2 in the active layer 6 as a function of the propagation direction 18. In particular, this Figure shows an example of a receiver 3, where a length 9 of the receiver 3 in propagation direction 18 is larger than an absorption length L_{abs} of electromagnetic radiation 2 within the active layer 6. After propagating a distance equal to the absorption length L_{abs}, about 63% of the electromagnetic radiation coupled into the receiver is absorbed in the active layer.

In addition, FIG. 6 shows a simplified equivalent circuit diagram of one active layer 6, where different regions of the active layer 6 in propagation direction 18 of the electromagnetic radiation 2 are represented by photodiodes 24, which are electrically connected in parallel. The output voltage of each photodiode 24 is proportional to the intensity I of the electromagnetic radiation. Consequently, the overall output voltage Vₒᵤₜ is determined by the photodiode 24, where the intensity I is smallest. In order to avoid this problem, the intensity I of electromagnetic radiation 2 in propagation direction 18 within the active layer 6 should be as homogenous as possible across the length 9 of the receiver 3. For example, the length 9 of the receiver 3 in propagation direction 18 may be smaller than the absorption length L_{abs} of electromagnetic radiation 2 inside the active layer 6. Furthermore, in order to increase an efficiency of the receiver 3, a second side face 13 of the receiver 3 opposite to the first side face 7 may comprise a highly reflective coating 14, such that electromagnetic radiation 2 emitted by the emitter 1 and coupled into the receiver 3 via the first side face 7 is reflected at the second side face 13 and further gradually absorbed in the active layer 6.

FIG. 7 shows a schematic cross-section of a receiver 3 according to an exemplary embodiment. In contrast to the exemplary embodiment in FIG. 1, here both the first side face 7 and the second side face 13 comprise a highly reflective coating 14. For example, the highly reflective coating 14 comprises an insulating dielectric coating covered with a metallic layer. Alternatively, the highly reflective coating 14 may comprise a dielectric mirror, comprising a plurality of dielectric layers with alternating refractive indices.

The highly reflective coatings 14 on the first side face 7 and the second side face 13 are configured as an optical resonator for electromagnetic radiation 2 generated by the emitter 1 and coupled into the receiver 3 via the first side face 7. A length 9 of the receiver 3 in propagation direction 18 is smaller than the absorption length L_{abs} of the electromagnetic radiation 2 inside the active layer 6. Electromagnetic radiation 2 thus passes between the two highly reflective coatings 14 multiple times before it is fully absorbed within the active layer 6. The optical resonator thus gives rise to a more homogenous intensity profile of electromagnetic radiation 2 in propagation direction 18 within the active layer 6.

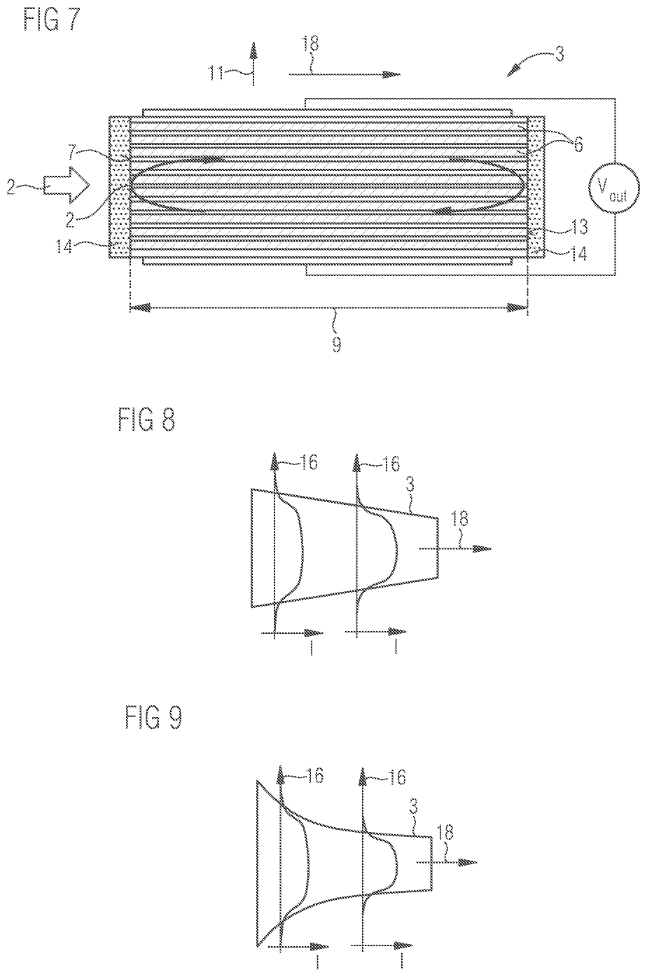

FIGS. 8 and 9 show schematic outlines of a receiver 3 in plan view of the main outer surface of the semiconductor layer sequence, together with schematic intensity I profiles of electromagnetic radiation 2 across the width 16 of the receiver 3 according to exemplary embodiments. In particular, the width 16 of the receiver 3 decreases as a function of a propagation direction 18 of electromagnetic radiation 2.

FIG. 8 shows a linear decrease of the width 16 of the receiver 3 in propagation direction 18, whereas FIG. 9 shows an exponential decrease of the width 16 of the receiver 3 in propagation direction 18 of the electromagnetic radiation 2. In both cases dielectric coatings 20 on side faces of the receiver 3 act as waveguides and compress the electromagnetic radiation 2 along the propagation direction 18, thereby increasing the intensity I of electromagnetic radiation 2 in propagation direction 18. In particular, the decreasing width 16 of the receiver 3 can be configured such that it compensates an absorption of electromagnetic radiation 2 inside active layers 6. Consequently, the intensity I profile of electromagnetic radiation 2 in propagation direction 18 is more homogenous.

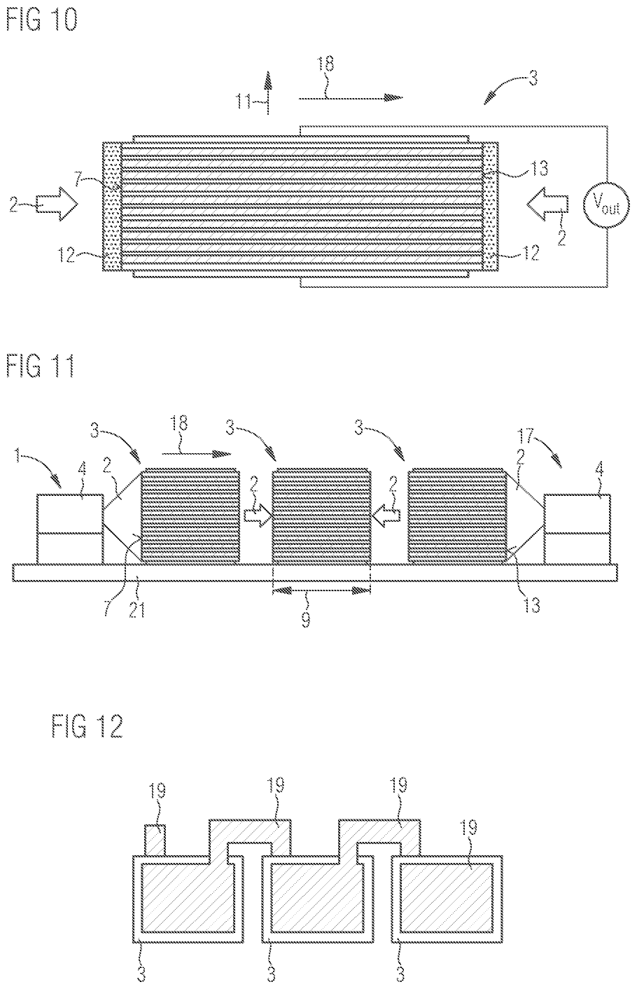

FIG. 10 shows a schematic cross-section of a receiver 3 according to a further exemplary embodiment. Here electromagnetic radiation 2 emitted by two emitters is coupled into the receiver 3 via opposing side faces 7, 13.

The superposition of counter-propagating electromagnetic radiation 2 within the active layers 6 gives rise to a more homogenous intensity profile of electromagnetic radiation 2 in propagation direction 18. The two opposing side faces 7, 13 are coated with anti-reflective coatings 12 to increase an incoupling efficiency of the electromagnetic radiation 2.

FIG. 11 shows a side cross-section of an optoelectronic device according to a further exemplary embodiment. Here, a plurality of receivers 3 is arranged next to each other and electrically connected in series. For simplicity only three receivers 3 are shown. However, the optoelectronic device may comprise less or more than three receivers 3. A length 9 of each receiver 3 in propagation direction 18 of electromagnetic radiation 2 is smaller than an absorption length L_{abs} of electromagnetic radiation 2 inside the active layer 6. The receivers 3 are arranged such that electromagnetic radiation 2 coupled into one receiver 3 via the first side face 7 and exiting the receiver 3 through the opposing second side face 13 after being partially absorbed within the receiver 3, is coupled into the following receiver 3 via its first side face 7.

All side faces 7, 13 of receivers 3 that are used for incoupling and/or outcoupling of electromagnetic radiation 2 emitted by an emitter 1, 17 preferably comprise an anti-reflective coating 12. The combined length of all receivers 3 is larger than the absorption length L_{abs} of electromagnetic radiation 2 inside the active layer 6. In this arrangement the intensity profile of electromagnetic radiation 2 in propagation direction 18 inside each receiver 3 is as homogenous as possible, whereas the total length of all receivers 3 is large enough to absorb the majority of electromagnetic radiation 2 emitted by the emitters 1, 17.

The optoelectronic device of the exemplary embodiment of FIGS. 11 and 12 has an optimized efficiency. The emitters 1, 17 and the receivers 3 are arranged on a common carrier 21. In this exemplary embodiment the plurality of receivers 3 is irradiated by two edge-emitting laser diodes 4 from two opposite sides. Alternatively, a single emitter 1 can be arranged together with the plurality of receivers 3 on a common carrier 21.

FIG. 12 shows a schematic plan view of the plurality of receivers 3 shown in FIG. 11. In particular, electrical contacts 19 are arranged on the receivers 3 such that the electrical contact 19 on an outer main surface of a receiver 3 is connected with the electrical contact 19 of a following receiver 3 on the opposite outer main surface. The electrical contacts 19 are arranged such that the plurality of receivers 3 is electrically connected in series.

The invention is not restricted to the exemplary embodiments by the description on the basis of said exemplary embodiments. Rather, the invention encompasses any new feature and also any combination of features, which in particular comprises any combination of features in the patent claims and any combination of features in the exemplary embodiments, even if this feature or this combination itself is not explicitly specified in the patent claims or exemplary embodiments.

1. An optoelectronic device comprising:
an emitter, operated with an electrical input voltage and configured to emit electromagnetic radiation during operation,
a receiver, configured to convert electromagnetic radiation emitted by the emitter to an output voltage, wherein
the receiver comprises a semiconductor layer sequence with a plurality of stacked active layers,
electromagnetic radiation emitted by the emitter is coupled into the receiver via a first side face of the semiconductor layer sequence,
the electromagnetic radiation propagates parallel to a main extension plane of the active layer inside the active layer, where it is gradually absorbed and converted into an electrical voltage, and
a length of the receiver in propagation direction of the electromagnetic radiation is smaller than an absorption length of the electromagnetic radiation in the active layer.

2. The optoelectronic device according to claim 1, wherein the emitter comprises an edge emitting laser diode.

3. The optoelectronic device according to claim 1, wherein two cladding layers are arranged on main faces of the active layer, such that the two cladding layers and the active layer form a waveguide for the electromagnetic radiation propagating inside the active layer.

4. The optoelectronic device according to claim 1, wherein a length of the receiver in propagation direction of the electromagnetic radiation is larger than a wavelength of the electromagnetic radiation.

5. The optoelectronic device according to claim 1, wherein a thickness of the active layers increases from a center of the receiver in a direction parallel to a growth direction of the semiconductor layer sequence.

6. The optoelectronic device according to claim 1, wherein
an optical element is arranged between the emitter and the receiver, and
the optical element is configured to homogenize an intensity profile of the electromagnetic radiation emitted by the emitter across the first side face of the semiconductor layer sequence of the receiver.

7. The optoelectronic device according to claim 1, wherein the first side face of the semiconductor layer sequence of the receiver comprises an antireflective coating.

8. The optoelectronic device according to claim 1, wherein a second side face of the semiconductor layer sequence of the receiver opposite to the first side face comprises a highly reflective coating.

9. The optoelectronic device according to claim 8, wherein
the first side face comprises a highly reflective coating, and
the first side face and the second side face form an optical resonator for electromagnetic radiation emitted by the emitter.

10. The optoelectronic device according to claim 1, wherein tunnel junctions are arranged between the active layers.

11. The optoelectronic device according to claim 10, wherein, a thickness of the tunnel junction is at most 100 nanometers.

12. The optoelectronic device according to claim 9, wherein
at least one active layer comprises a multi-quantum well structure comprising indium gallium arsenide, and
at least one tunnel junction comprises gallium arsenide.

13. The optoelectronic device according to claim 9, wherein
at least one active layer with a bulk pn-junction comprises gallium arsenide, and
at least one tunnel junction comprises aluminium gallium arsenide.

14. The optoelectronic device according to claim 1, wherein a width of the receiver in a direction perpendicular to the growth direction of the semiconductor layer sequence and perpendicular to the propagation direction of the electromagnetic radiation in the active layers decreases in the propagation direction.

15. The optoelectronic device according to claim 1, further comprising a second emitter configured to emit electromagnetic radiation during operation, wherein electromagnetic radiation emitted by the second emitter is coupled into the receiver via a second side face of the semiconductor layer sequence opposite to the first side face.

16. The optoelectronic device according to claim 15, wherein wavelengths of electromagnetic radiation emitted by the two emitters differ by not more than 10 Nanometers.

17. The optoelectronic device according to claim 15, further comprising a plurality of receivers arranged next to each other on a common substrate and electrically connected to each other in series, wherein the plurality of receivers is arranged between the two emitters.
